(19) United States
(12) Patent Application Publication
(10) Pub. No.: US 2026/0242641 A1
(43) Pub. Date: Aug. 20, 2026

(54) THERMALLY CONDUCTIVE SILICONE ADHESIVE COMPOSITION

(71) Applicant: Henkel AG & Co. KGaA, Düsseldorf (DE)

(72) Inventors: Xingyu Zhu, Shanghai (CN); Dan Xie, Shanghai (CN); Xiaodan Chen, Shanghai (CN); Yan Chen, Shanghai (CN)

(21) Appl. No.: 19/640,858

(22) Filed: Apr. 7, 2026

Related U.S. Application Data
(63) Continuation of application No. PCT/CN2023/124405, filed on Oct. 13, 2023.

(51) Int. Cl. C09J 11/04; C08G 77/20; C08K 3/22; C08K 3/34; C08K 5/5415; C09J 5/00; C09J 11/06; C09J 183/04; C09K 5/14; H10W 40/00; H10W 40/25

(52) U.S. Cl. CPC C09J 11/04; C08G 77/20; C09J 5/00; C09J 11/06; C09J 183/04; C09K 5/14; H10W 40/037; H10W 40/251; C08K 2003/2227; C08K 2003/2296; C08K 3/34; C08K 5/5415; C08K 2201/005

(57) ABSTRACT

The present invention relates to a thermally conductive silicone adhesive composition comprising: (A) an alkenyl group-containing organopolysiloxane; (B) an alkyl group-terminated organopolysiloxane; (C) a silane coupling agent; (D) a catalyst; and (E) a mixture of (e−1) alumina having a D₅₀ particle size of 4 to 8 μm, (e−2) silicon carbide having a D₅₀ particle size of 1 to 4 μm, and (e−3) alumina and/or zinc oxide having a D₅₀ particle size less than 1 μm, wherein the thermally conductive silicone adhesive composition exhibits a low thermal impedance, a low viscosity which is suitable for printing process, a high breakdown voltage, and a good anti-pump-out performance.

### TECHNICAL FIELD

The present invention relates to a thermally conductive silicone adhesive composition, and in particular relates to a thermally conductive silicone adhesive composition exhibiting a low thermal impedance, a low viscosity which is suitable for printing process, a high breakdown voltage, and a good anti-pump-out performance.

### BACKGROUND OF THE INVENTION

In recent years, along with size reduction and performance enhancement of electronic device, there is an increasing demand for thermally conductive silicone greases in terms of thermal conductivity, viscosity, electrical insulation and an anti-pump-out performance. In particular, all the prior silicone greases in the market cannot meet the requirements of a thermal impedance lower than 0.06 K·cm²/W, a viscosity of 100 to 300 Pa·s at 25° C., a breakdown voltage higher than 3 kV/mm, and a good anti-pump-out performance of −40 to 125° C. for 200 cycles at the same time.

In view of the above, it would be desirable to provide a thermally conductive silicone composition which exhibits a low thermal impedance, a low viscosity which is suitable for printing process, a high breakdown voltage, and a good anti-pump-out performance.

### SUMMARY OF THE INVENTION

The present invention provides a thermally conductive silicone adhesive composition comprising:
(A) an alkenyl group-containing organopolysiloxane;
(B) an alkyl group-terminated organopolysiloxane;
(C) a silane coupling agent;
(D) a catalyst; and
(E) a mixture of (e-1) alumina having a D₅₀ particle size of 4 to 8 μm, (e-2) silicon carbide having a D₅₀ particle size of 1 to 4 μm, and (e-3) alumina and/or zinc oxide having a D₅₀ particle size less than 1 μm.

The present invention also provides a cured product of the thermally conductive silicone adhesive composition according to the present invention.

The present invention further provides a use of the thermally conductive silicone adhesive composition according to the present invention or the cured product according to the present invention in manufacturing electronic devices.

All of the thermally conductive silicone adhesive composition, the cured product, and the use according to the present invention are based on the following surprising discoveries of the inventors: the thermally conductive silicone adhesive composition according to the present invention, which utilizes a specific combination of components (A) to (E), especially a specific combination of components (e-1), (e−2) and (e-3), exhibits a low thermal impedance, a low viscosity which is suitable for printing process, a high breakdown voltage, and a good anti-pump-out performance; and in particular, it exhibits a thermal impedance lower than 0.06 K·cm²/W, a viscosity of 100 to 300 Pa·s at 25° C., a breakdown voltage higher than 3 kV/mm, and a good anti-pump-out performance of −40 to 125° C. for 200 cycles at the same time.

### DETAILED DESCRIPTION OF THE INVENTION

It is to be understood by one of ordinary skill in the art that the present discussion is a description of exemplary embodiments only and is not intended as limiting the broader aspects of the present invention. Each aspect so described may be combined with any other aspect or aspects unless clearly indicated to the contrary. In particular, any feature indicated as being preferred or advantageous may be combined with any other feature or features indicated as being preferred or advantageous.

Unless specified otherwise, as used herein, the terms “a”, “an” and “the” include both singular and plural referents.

The terms “comprising” and “comprises” as used herein are synonymous with “including”, “includes”, “containing” or “contains”, and are inclusive or open-ended and do not exclude additional, non-recited members, elements or process steps.

Unless specified otherwise, the recitation of numerical end points includes all numbers and fractions subsumed within the respective ranges, as well as the recited end points.

Unless specified otherwise, all the term “room temperature” used herein refers to 23±2° C.

Unless specified otherwise, all the molecular weights used herein refers to weight average molecular weights (Mw), which are obtained by gel permeation chromatography (GPC) according to DIN 55672.

Unless specified otherwise, all the “D₅₀ particle size” used herein represents a median diameter in a volume-basis particle size distribution curve obtained by measurement with a laser diffraction particle size analyzer.

Unless specified otherwise, all the parameters used herein are measured according to the methods as stated in the working examples of the present description, if any.

Unless otherwise defined, all terms used in disclosing the invention, including technical and scientific terms, have the meaning as commonly understood by one of the ordinary skill in the art to which this invention belongs.

According to the present invention, surprisingly, the inventors of the present invention found that a thermally conductive silicone adhesive composition comprising:
(A) an alkenyl group-containing organopolysiloxane;
(B) an alkyl group-terminated organopolysiloxane;
(C) a silane coupling agent;
(D) a catalyst; and
(E) a mixture of (e-1) alumina having a D₅₀ particle size of 4 to 8 μm, (e-2) silicon carbide having a D₅₀ particle size of 1 to 4 μm, and (e-3) alumina and/or zinc oxide having a D₅₀ particle size less than 1 μm,
   exhibits a low thermal impedance, a low viscosity which is suitable for printing process, a high breakdown voltage, and a good anti-pump-out performance.

In a first aspect, the present disclosure is generally directed to a thermally conductive silicone adhesive composition comprising:
(A) an alkenyl group-containing organopolysiloxane;
(B) an alkyl group-terminated organopolysiloxane;
(C) a silane coupling agent;
(D) a catalyst; and
(E) a mixture of (e-1) alumina having a D₅₀ particle size of 4 to 8 μm, (e-2) silicon carbide having a D₅₀ particle size of 1 to 4 μm, and (e-3) alumina and/or zinc oxide having a D₅₀ particle size less than 1 μm.

### Alkenyl Group-Containing Organopolysiloxane

According to the present invention, the thermally conductive silicone adhesive composition comprises (A) an alkenyl group-containing organopolysiloxane.

As used herein, “alkenyl” refers to a radical of a straight-chain or branched hydrocarbon group having from 2 to 40 carbon atoms and one or more carbon-carbon double bonds (e.g., 1, 2, 3, or 4 double bonds) (“C₂₋₄₀ alkenyl”). In some embodiments, an alkenyl group has 2 to 30 carbon atoms (“C₂₋₃₀ alkenyl”). In some embodiments, an alkenyl group has 2 to 20 carbon atoms (“C₂₋₂₀ alkenyl”). In some embodiments, an alkenyl group has 2 to 10 carbon atoms (“C₂₋₁₀ alkenyl”). In some embodiments, an alkenyl group has 2 to 9 carbon atoms (“C₂₋₉ alkenyl”). In some embodiments, an alkenyl group has 2 to 8 carbon atoms (“C₂₋₈ alkenyl”). In some embodiments, an alkenyl group has 2 to 7 carbon atoms (“C₂₋₇ alkenyl”). In some embodiments, an alkenyl group has 2 to 6 carbon atoms (“C₂₋₆ alkenyl”). In some embodiments, an alkenyl group has 2 to 5 carbon atoms (“C₂₋₅ alkenyl”). In some embodiments, an alkenyl group has 2 to 4 carbon atoms (“C₂₋₄ alkenyl”). In some embodiments, an alkenyl group has 2 to 3 carbon atoms (“C₂₋₃ alkenyl”). In some embodiments, an alkenyl group has 2 carbon atoms (“C₂ alkenyl”). The one or more carbon-carbon double bonds can be internal (such as in 2-butenyl) or terminal (such as in 1-butenyl). Examples of C₂₋₄ alkenyl groups include ethenyl (C₂), 1-propenyl (C₃), 2-propenyl (C₃), 1-butenyl (C₄), 2-butenyl (C₄), butadienyl (C₄), and the like. Examples of C₂₋₆ alkenyl groups include the aforementioned C₂₋₄ alkenyl groups as well as pentenyl (C₅), pentadienyl (C₅), hexenyl (C₆), and the like. Additional examples of alkenyl include heptenyl (C₇), octenyl (Cs), octatrienyl (Cs), and the like. Unless otherwise specified, each instance of an alkenyl group is independently unsubstituted (an “unsubstituted alkenyl”) or substituted (a “substituted alkenyl”) with one or more substituents. In certain embodiments, the alkenyl group is an unsubstituted C₂₋₃₀ alkenyl. In certain embodiments, the alkenyl group is a substituted C₂₋₃₀ alkenyl.

In some embodiments, the quantity of alkenyl groups is within a range from 0.01 to 10 wt. %, and preferably from 0.1 to 5 wt. % based on the total weight of the alkenyl group-containing organopolysiloxane.

In some embodiments, the viscosity at 25° C. of the component (A) is lower than 1000 mPa's, preferably lower than 500 mPa·s, and more preferably lower than 200 mPa·s. The viscosity herein was measured with TA Rheometer parallel plate using spindle 25 mm under 60 rpm, 25° C.

There are no particular restrictions on the molecular structure of the component (A), including but being not limited to straight chain structures, cyclic structures, branched chain structures, partially branched straight chain structures and three-dimensional network structures. Furthermore, the component (A) may be a single polymer with this type of molecular structure, a copolymer with this type of molecular structure, or a mixture of different polymers with this type of molecular structure.

Specific examples of the component (A) include the compounds represented by the general formulae (i) to (v) as shown below.

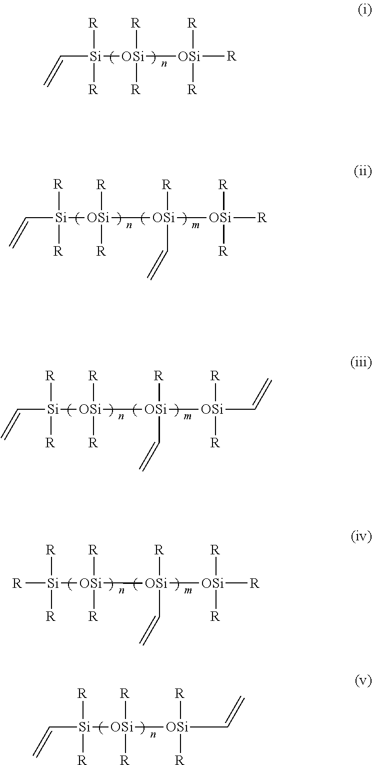

In the formulae (i) to (v) above, R each independently represents a substituted or unsubstituted monovalent hydrocarbon group bonded to a silicon atom, but excluding alkenyl groups, as described above, and is preferably a methyl group or a phenyl group. In the formulae (i) to (v), n is an integer of from 0 to 5000, m is an integer of from 5 to 5000, and the sum of n and m ranges from 5 to 10000. In some embodiments, n ranges from as little as 0, 10, 50, 100, 200, 500, as great as 1000, 2000, 5000, or within any range defined between any two of the foregoing values; and m ranges from 5, 10, 50, 200, or as great as 500, 1000, 2000, 5000, or within any range defined between any two of the foregoing values. In addition, the sum of n and m ranges from as little as 5, 10, 30, 50, 100, 200, 500, or great as 1000, 2000, 5000, 10000, or within any range defined between any two of the foregoing values, such as between 10 and 10000, and between 1000 and 5000.

In some embodiments, the unsubstituted or substituted monovalent hydrocarbon group R in the formulae (i) to (v) above is each independently selected from straight-chain alkyl groups, preferably selected from methyl group, ethyl group, n-propyl group, n-butyl group, n-pentyl group, n-hexyl group, n-heptyl group, n-octyl group, n-nonyl group, n-decyl group, n-undecyl group, n-dodecyl group, n-tridecyl group, n-tetradecyl group, n-pentadecyl group, n-hexadecyl group, n-heptadecyl group, n-octadecyl group, n-nonadecyl group, and n-eicosyl group; branched-chain alkyl groups, preferably selected from isopropyl group, t-butyl group, isobutyl group, 2-methylundecyl group, and 1-hexylheptyl group; cyclic alkyl groups, preferably selected from a cyclopentyl group, cyclohexyl group, and cyclododecyl group; aryl groups, preferably selected from a phenyl group, tolyl group, and xylyl group; aralkyl groups, preferably selected from a benzyl group, phenethyl group, and 2-(2,4,6-trimethylphenyl) propyl group; and halogenated alkyl groups, preferably selected from 3,3,3-trifluoropropyl group and 3-chloropropyl group; preferably selected from straight-chain alkyl groups and aryl groups; and more preferably selected from methyl group, ethyl group and phenyl groups.

In one preferred embodiment, component (A) is selected from vinyl terminated polydimethylsiloxane, vinyl terminated diphenylsiloxane-dimethylsiloxane copolymer, vinyl terminated polyphenylsiloxane, vinylbenzyl terminated vinylphenylsiloxane-phenylmethylsiloxane copolymer, vinyl terminated trifluoropropylmethylsiloxane-dimethylsiloxane copolymer, vinyl terminated diethylsiloxane-dimethylsiloxane copolymer, vinylmethylsiloxane-dimethylsiloxane copolymer, trimethylsilanyl terminated vinylmethylsiloxane-dimethylsiloxane copolymer, silanol terminated vinylmethylsiloxane-dimethylsiloxane copolymer, vinylmethylsiloxane homopolymer, vinylmethylsiloxane copolymer, vinyl terminated poly(methyl siloxane) copolymer, vinyl terminated poly(methyl siloxane) copolymer, vinyl terminated poly(methyl siloxane) copolymer, poly(vinyl terminated poly(methyl siloxane) copolymer, poly (vinyl terminated poly(vinyl siloxane) and poly(vinyl siloxane) copolymer, monovinyl-terminated polydimethylsiloxane, vinylmethylsiloxane terpolymers, vinylmethoxysilane homopolymers, or combination thereof.

There are no particular restrictions on the molecular weight of component (A), and preferably in the range of from 3000 to 20,000 g/mol.

The component (A) may be used either alone, or in combinations of two or more different compounds.

Such alkenyl group-containing organopolysiloxane used as component (A) can be produced using conventionally known methods. In a typical production method, the alkenyl group-containing organopolysiloxane is produced by conducting an equilibration reaction of an organocyclooligosiloxane and a hexaorganodisiloxane in the presence of either an alkali or acid catalyst.

Preferably, the component (A) is a vinyl terminated polydimethylsiloxane having a viscosity lower than 200 mPa·s at 25° C.

Examples of commercially available products of the component (A) include, but are not limited to: vinyl terminated polydimethylsiloxane RH Vi392, RH Vi393, RH Vi395, RH Vi321, RH Vi322, RH Vi311, RH Vi305, RH Vi70E, RH Vi100E, RH Vi500E, and RH Vi1000E, all of which are available from Zhejiang Runhe Chemical New Material Co., Ltd; and Andisil™ VS 20, Andisil™ VS 50, Andisil™ VS 100, Andisil™ VS 200, Andisil™ VS 500, and Andisil™ VS 100, all of which are available from AB Specialty Silicones. Preferably, the component (A) is selected from the group consisting of RH Vi 393, RH Vi70E, and RH Vi100E, all of which are available from Zhejiang Runhe Chemical New Material Co., Ltd. More preferably, the component (A) is RH Vi100E available from Zhejiang Runhe Chemical New Material Co., Ltd.

Preferably, the component (A) is present in an amount of from 0.01 to 5%, preferably 1 to 4% by weight, more preferably 2 to 3.5% by weight, and even more preferably from 2.5 to 3% by weight, each based on the total weight of the composition.

### (B) Alkyl Group-Terminated Organopolysiloxane

According to the present invention, the thermally conductive silicone adhesive composition comprises (B) an alkyl group-terminated organopolysiloxane.

As used herein, “alkyl” refers to a radical of a straight-chain or branched hydrocarbon group having from 1 to 5 carbon atoms (“C₁₋₅ alkyl”), such as methyl, ethyl, propyls, butyls and pentyls.

Preferably, the alkyl group-terminated organopolysiloxane may be an alkyl group-terminated polydimethylsiloxane, and preferably a methyl-terminated polydimethylsiloxane.

In some embodiments, the viscosity at 25° C. of the component (B) is lower than 1000 mPa's, preferably lower than 500 mPa·s, and more preferably lower than 200 mPa·s. The viscosity herein was measured with TA Rheometer parallel plate using spindle 25 mm under 60 rpm, 25° C.

Preferably, the component (B) is a methyl-terminated polydimethylsiloxane having a viscosity lower than 200 mPa·s at 25° C.

Examples of commercially available products of the component (B) include, but are not limited to: RH201-20, RH201-50, and RH201-100, all of which are available from Zhejiang Runhe Chemical New Material Co., Ltd; H201-20, H201-50, and H201-100, all of which are available from AB silicones; and H201-20, H201-50, and H201-100, all of which are available from Sinopharm. Preferably, the component (B) is H201-50 available from Sinopharm.

Preferably, the component (B) is present in an amount of from 0.01 to 5%, preferably 1 to 4% by weight, more preferably 2 to 3.5% by weight, and even more preferably from 2.5 to 3.1% by weight, each based on the total weight of the composition.

### (C) Silane Coupling Agent

According to the present invention, the thermally conductive silicone adhesive composition comprises (C) a silane coupling agent.

Preferably, the silane coupling agent (C) is selected from the general formulae (I) to (III) shown below and mixtures thereof:

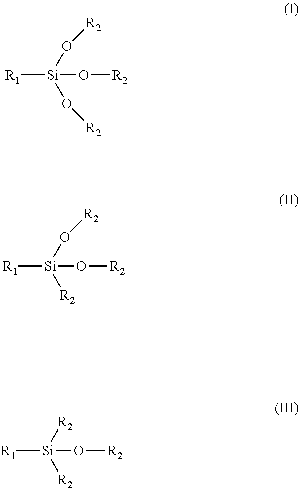

wherein in each general formulae (I), (II) and (III), R₁ independently represents hydrogen or a vinyl group, and R₂ independently represents an alkyl group having 1 to 4 carbon atoms. In a preferred embodiment of the present invention, R₁ independently represents hydrogen; and/or R₂ independently represents methyl. In another preferred embodiment of the present invention, the component (C) is a silane coupling agent shown by the formula (I).

Examples of the silane coupling agent used in the present invention includes, but are not limited to, trimethoxysilane, dimethoxy(methyl)silane, dimethoxy(ethyl)silane, dimethoxy(propyl)silane, dimethoxy(butyl)silane, vinyltrimethoxysilane, vinyltriethoxysilane, and vinyldimethoxy(meth)silane. Preferably, the silane coupling agent is trimethoxysilane.

Examples of commercially available products of the component (C) include, but are not limited to: trimethoxysilane available from Sinopharm, TCI and Sigma-Aldrich; dimethoxy(methyl)silane available from Sinopharm, TCI and Sigma-aldrich; dimethoxymethylvinylsilane available from Sinopharm, TCI, Sigma-aldrich, Momentive and Wacker, such as Silquest A 2171 available from Momentive and Geniosil XL 12 available from Wacker; and vinyltrimethoxysilane available from Sinopharm, TCI, Sigma-aldrich, Momentive, Wacker and Evonik, such as Silquest A 171 available from Momentive, Geniosil XL 10 available from Wacker, and Dynasylan VTMO available from Evonik. Preferably, the component (C) is trimethoxysilane available from Sinopharm.

Preferably, the component (C) is present in an amount of from 0.01 to 0.9%, preferably 0.05 to 0.5% by weight, more preferably 0.07 to 0.2% by weight, and even more preferably from 0.08 to 0.11% by weight, each based on the total weight of the composition.

### (D) Catalyst

According to the present invention, the thermally conductive silicone adhesive composition comprises (D) a catalyst.

Preferably, a catalyst well-known as a catalyst used in a hydrosilylation reaction may be used. In a preferred embodiment of the present invention, the component (D) is a platinum-based catalyst. Examples of commercially available Pt catalyst include but are not limited to those available from Evonik, Gelest and Nusil. Preferably, the component (D) is Pt catalyst 540, with 0.2 wt % Pt ratio, available from Evonik.

Preferably, the component (D) is present in an amount of from 0.0005 to 0.1%, and preferably 0.001 to 0.05% by weight, each based on the total weight of the composition.

(E) Mixture of Components (e-1), (e-2) and (e-3)

According to the present invention, the thermally conductive silicone adhesive composition comprises (E) a mixture of (e-1) alumina having a D₅₀ particle size of 4 to 8 μm, (e-2) silicon carbide having a D₅₀ particle size of 1 to 4 μm, and (e-3) alumina and/or zinc oxide having a D₅₀ particle size less than 1 μm.

(e-1) Alumina Having a D₅₀ Particle Size of 4 to 8 μm

In a preferred embodiment of the present invention, the component (e-1) has a D₅₀ particle size of 4.5 to 7 μm, preferably of 5 to 6 μm, and more preferably of 5 μm.

Examples of commercially available component (e-1) include, but are not limited to: AA-5, alumina having a D₅₀ particle size of 5 μm, available from Sumitomo in Japan; BAK 5, available from Bestry in China; and SFADW 5 available from CMP in China. Preferably, the component (e-1) is AA-5, alumina having a D₅₀ particle size of 5 μm, available from Sumitomo in Japan.

Preferably, the component (e-1) is present in an amount of from 10 to 80% by weight, more preferably from 20 to 63% by weight, even more preferably from 30 to 55% by weight, and most preferably from 34 to 49% by weight, each based on the total weight of the composition. In a preferred embodiment of the present invention, the component (e-1) is present in an amount of 49% by weight, based on the total weight of the composition.
(e-2) silicon carbide having a D₅₀ particle size of 1 to 4 μm

In a preferred embodiment of the present invention, the component (e-2) has a D₅₀ particle size of 1.5 to 3.5 μm, preferably of 2 to 3 μm, and more preferably of 2.5 μm.

Examples of commercially available component (e-2) include, but are not limited to: SiC 2.5 μm, silicon carbide having a D₅₀ particle size of 2.5 μm, available from GNF Graystar in US, Fiven in Norway, Pacific Rundom in Japan, and Eno material, Boer material, Hongwu nano in China. Preferably, the component (e-2) is SiC 2.5 μm, silicon carbide having a D₅₀ particle size of 2.5 μm, available from Xi'an Boer material.

Preferably, the component (e-2) is present in an amount of from 5 to 70% by weight, more preferably from 15 to 50% by weight, even more preferably from 20 to 45% by weight, and most preferably from 25 to 40% by weight, each based on the total weight of the composition. In a preferred embodiment of the present invention, the component (e-2) is present in an amount of 25% by weight, based on the total weight of the composition.

(e-3) Alumina and/or Zinc Oxide Having a D₅₀ Particle Size Less than 1 μm

In a preferred embodiment of the present invention, the component (e-3) has a D₅₀ particle size less than 0.8 μm, preferably less than 0.6 μm, more preferably less than 0.4 μm, and even more preferably of 0.3 μm.

Preferably, the component (e-3) used in the present invention is alumina has a D₅₀ particle size less than 1 μm.

Examples of commercially available component (e-3) include, but are not limited to: AA-03F, alumina having a D₅₀ particle size of 0.3 μm, available from Sumitomo; and Zoco 103, zinc oxide having a D₅₀ particle size of 0.3 μm, available from Zochem. Preferably, the component (e-3) is AA-03F, alumina having a D₅₀ particle size of 0.3 μm, available from Sumitomo.

Preferably, the component (e-3) is present in an amount of from 1 to 40% by weight, more preferably from 10 to 30% by weight, and even more preferably from 15 to 25% by weight, each based on the total weight of the composition. In a preferred embodiment of the present invention, the component (e−3) is present in an amount of 20% by weight, based on the total weight of the composition.

In a preferred embodiment of the present invention, the thermally conductive silicone adhesive composition according to the present invention contains no filler except the component (E).

### Optional Additive

In some embodiments of the present invention, the thermally conductive silicone adhesive composition according to the present invention may further optionally comprise additives which are commonly used in the art to which the present invention belongs, such as inhibitors, pigments, dyes, fluorescent dyes, heat resistant additives, flame retardants, plasticizers, adhesion-imparting agents and combinations thereof, as long as they do not negatively affect the desired technical effects of the inventive composition. The presence, the type and the amount of the additive can be determined by a specialist in the art according to actual requirements.

The thermally conductive silicone adhesive composition according to the present invention may be prepared by any conventional preparation methods in the art. Preferably, the composition according to the present invention may be prepared by mixing all the components therein at room temperature in a conventional mixing device, such as a planetary mixer or speedmixer.

The thermally conductive silicone adhesive composition according to the present invention may be applied to the desired substrate by any conventional technique. It may be applied cold or be applied warm if desired. It may be applied by extruding or pasting it onto the substrate or other mechanical application methods such as a caulking gun. Generally, the thermally conductive silicone adhesive composition of the present invention is applied to one surface of a pair of substrates, and then the substrates are contacted with each other to be bonded together. After application, the thermally conductive silicone adhesive composition of the present invention cures at room temperature, optionally followed by curing at elevated temperature.

In a second aspect, the present disclosure is directed to a cured product of the thermally conductive silicone adhesive composition according to the present invention.

In a third aspect, the present disclosure is directed to a use of the thermally conductive silicone adhesive composition or the cured product according to the present invention in manufacturing electronic devices, particularly in Insulate-Gate Bipolar Transistor (IGBT) module for power, and telecom and datacom devices, such as 5G station.

Exemplary electronic devices encompass computers and computer equipment, such as telecom and datacom devices, such as 5G station, or the like; printers, fax machines, scanners, keyboards and the like; medical sensors; automotive sensors and the like; wearable electronic devices (e.g., wrist watches and eyeglasses) and their integrated circuit elements, handheld electronic devices (e.g., phones (e.g., cellular telephones and cellular smartphones) and their integrated circuit elements, cameras, tablets, electronic readers, monitors (e.g., monitors used in hospitals, and by healthcare workers, athletes and individuals), watches, calculators, mice, touch pads, and joy sticks), computers (e.g., desk top and lap top computers) and their integrated circuit elements, computer monitors, televisions, media players, household appliances (e.g., refrigerators, washing machines, dryers, ovens, and microwaves), light bulbs (e.g., incandescent, light emitting diode, and fluorescent), and articles that include a visible transparent or transparent component, glass housing structures, protective transparent coverings for a display or other optical component.

The thermally conductive silicone adhesive composition according to the present invention, which utilizes a specific combination of components (A) to (E), especially a specific combination of components (e-1), (e-2) and (e-3), exhibits a low thermal impedance, a low viscosity which is suitable for printing process, a high breakdown voltage, and a good anti-pump-out performance; and in particular, it exhibits a thermal impedance lower than 0.06 K·cm²/W, a viscosity of 100 to 300 Pa·s at 25° C., a breakdown voltage higher than 3 kV/mm, and a good anti-pump-out performance of −40 to 125° C. for 200 cycles at the same time.

### EXAMPLES

The following examples are intended to assist one skilled in the art to better understand and practice the present disclosure. The scope of the invention is not limited by the examples but is defined in the appended claims. All parts and percentages are based on weight unless otherwise stated.

### Raw Materials:

### Component (A):

Component a: RH Vi100E, a vinyl terminated polydimethylsiloxane having a viscosity of 100 mPa·s, available from Zhejiang Runhe Chemical New Material Co., Ltd.

### Component (B):

Component b: H201-50, a methyl-terminated polydimethylsiloxane having a viscosity of 50 mPa·s, available from Sinopharm.

### Component (C):

Component c: trimethoxysilane, having a chemical structure of

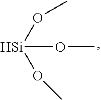

available from Sinopharm.

### Component (D):

Component d: Pt catalyst 540, with 0.2 wt % Pt ratio, available from Evonik.

### Component (E):

Component (e-1):
Component e-1-1: AA-5, alumina having a D₅₀ particle size of 5 μm, available from Sumitomo.
Component e-1-2′: BAK-10, alumina having a D₅₀ particle size of 10 μm, available from Bestry.
   Component (e-2):
Component e-2-1: SiC 2.5 μm, silicon carbide having a D₅₀ particle size of 2.5 μm, available from Xi'an Boer material.
Component e-2-2′: SiC 5 μm, silicon carbide having a D₅₀ particle size of 5 μm, available from Boer material.
Component e-2-3′: SiC 20 μm, silicon carbide having a D₅₀ particle size of 20 μm, available from Boer material.
Component e-2-4′: FB-72F, zinc oxide having a D₅₀ particle size of 1 μm, available from Guangdong Jinge Material Co., Ltd.
Component e-2-5′: AA-3, alumina having a D₅₀ particle size of 3 μm, available from Sumitomo.
   Component (e-3):
Component e-3-1: AA-03F, alumina having a D₅₀ particle size of 0.3 μm, available from Sumitomo.
Component e-3-2: Zoco 103, zinc oxide having a D₅₀ particle size of 0.3 μm, available from Zochem.

### Preparation of Examples 1-9 (Ex. 1 to Ex. 9)

Specific amounts and types of components in the thermally conductive silicone adhesive compositions of Examples 1 to 9 are shown in Tables 1 to 2 as below. The compositions were prepared as follows: mixing all the components therein in a planetary mixer at a blade speed of 30 RPM with a high shear dispenser at a speed of 800 RPM for 1 hour, during which vacuum was applied to evacuate the air bubbles in the mixture under 0.1 Mpa. The mixing equipment used was 1.5 L ROSS mixer made from Charles Ross & Son Company.

### Test Methods:

### Thermal Impedance

For each of the compositions of Ex. 1 to Ex. 9, the thermal impedance was tested according to the standard ASTM D5470 with Longwin 9389 from Long Win Science and Technology Corporation under 40 psi and a temperature of 80° C.

In the present invention, a thermally conductive silicone adhesive composition which exhibits a thermal impedance lower than 0.06 K·cm²/W is desired, and the lower the better.

### Viscosity at 25° C.

For each of the compositions of Ex. 1 to Ex. 9, the viscosity was measured at 25° C. with a TA rheometer DHR20 using a parallel plate 25 mm with shear rate 10/s and 0.5 mm gap following ASTM D₄₀₉₂.

In the present invention, a thermally conductive silicone adhesive composition which exhibits a viscosity at 25° C. of 100 to 300 Pa·s is desired.

### Breakdown Voltage

For each of the compositions of Ex. 1 to Ex. 9, the breakdown voltage was measured with Hipot tester from Electron Instruments following ASTM 149, in which the sample thickness was 1 mm.

In the present invention, a thermally conductive silicone adhesive composition which exhibits a breakdown voltage higher than 3 kV/mm is desired, and the higher the better.

### Anti-Pump-Out Performance

For each of the compositions of Ex. 1 to Ex. 9, the composition was printed on the Aluminium substrate with stencil mesh at a thickness of 0.1 mm, a IGBT module with Ni coated copper plate was assembled to the substrate with 5 Nm screw force, and then the module was place into a thermal cycle oven with-40 to 125° C. for 200 cycles; and after the thermal cycle aging, the anti-pump-out performance was check visually. In particular, when there were equal to or higher than 30% voids in surface, the composition was evaluated as “fail”; when there were less than 30% but higher than 10% voids in surface, the composition was evaluated as “pass”; and when there were equal to or less than 10% voids in surface, the composition was evaluated as “good”.

In the present invention, a thermally conductive silicone adhesive composition which exhibits a good anti-pump-out performance is desired.

The thermal impedance, the viscosity, the breakdown voltage, and the anti-pump-out performance of the compositions were tested using the methods stated above respectively, and the results thereof are shown in Tables 1-2 as below.

TABLE 1

| Components | | | | | | | |
|---|---|---|---|---|---|---|---|
| (weight in g) | | Ex. 1 | Ex. 2 | Ex. 3 | Ex. 4 | Ex. 5 | Ex. 6 |
| (A) | A | 2.899 | 2.899 | 2.899 | 2.899 | 2.899 | 2.899 |
| (B) | B | 3.000 | 3.000 | 3.000 | 3.000 | 3.000 | 3.000 |
| (C) | C | 0.100 | 0.100 | 0.100 | 0.100 | 0.100 | 0.100 |
| (D) | D | 0.001 | 0.001 | 0.001 | 0.001 | 0.001 | 0.001 |
| (E) | e-1-1 | 49.000 | 49.000 | 49.000 | 49.000 | 49.000 | 49.000 |
| | e-1-2′ | — | — | — | — | — | — |
| | e-2-1 | 25.000 | — | — | — | — | 10.000 |
| | e-2-2′ | — | — | — | — | 25.000 | — |
| | e-2-3′ | — | — | — | 25.000 | — | — |
| | e-2-4′ | — | 25.000 | — | — | — | — |
| | e-2-5′ | — | — | 25.000 | — | — | 15.000 |
| | e-3-1 | 20.000 | 20.000 | 20.00 | 20.000 | 20.000 | 20.000 |
| | e-3-2 | — | — | — | — | — | — |

| Test results | Ex. 1 | Ex. 2 | Ex. 3 | Ex. 4 | Ex. 5 | Ex. 6 |
|---|---|---|---|---|---|---|
| Thermal impedance | 0.051 | 0.081 | 0.078 | 0.121 | 0.071 | 0.062 |
| (K · cm²/W) | | | | | | |
| Viscosity at 25° C. (Pa · s) | 135 | 185 | 114 | 87 | 180 | 122 |
| Breakdown Voltage | 4.5 | 6.8 | 8.8 | 2.7 | 3.2 | 5.5 |
| (Kv/mm) | | | | | | |
| Anti-pump-out | good | good | pass | pass | good | pass |
| performance | | | | | | |

TABLE 2

| Components (weight in g) | | Ex.7 | Ex.8 | Ex.9 |
|---|---|---|---|---|
| (A) | A | 2.899 | 2.899 | 2.899 |
| (B) | B | 3.000 | 3.000 | 3.000 |
| (C) | C | 0.100 | 0.100 | 0.100 |
| (D) | D | 0.001 | 0.001 | 0.001 |
| (E) | e-1-1 | 34.000 | — | 49.000 |
| | e-1-2′ | — | 49.000 | — |
| | e-2-1 | 40.000 | 25.000 | 25.000 |
| | e-2-2′ | — | — | — |
| | e-2-3′ | — | — | — |
| | e-2-4′ | — | — | — |
| | e-2-5′ | — | — | — |
| | e-3-1 | 20.000 | 20.000 | — |
| | e-3-2 | — | — | 20.000 |

| Test Results | Ex.7 | Ex.8 | Ex.9 |
|---|---|---|---|
| Thermal impedance (K.cm²/W) | 0.055 | 0.098 | 0.057 |
| Viscosity at 25° C. (Pa.s) | 200 | 85 | 289 |
| Breakdown Voltage(Kv/mm) | 3.8 | 4.7 | 4.2 |
| Anti-pump-out performance | good | good | good |

From the data in Tables 1 and 2, it can be seen that thermally conductive silicone adhesive composition according to the present invention (Ex. 1, Ex. 7 and Ex. 9), which utilizes a specific combination of components (A) to (E), especially a specific combination of components (e-1), (e-2) and (e-3), exhibits a low thermal impedance, a low viscosity which is suitable for printing process, a high breakdown voltage, and a good anti-pump-out performance; and in particular, it exhibits a thermal impedance lower than 0.06 K·cm²/W, a viscosity of 100 to 300 Pa·s at 25° C., a breakdown voltage higher than 3 kV/mm, and a good anti-pump-out performance of −40 to 125° C. for 200 cycles at the same time. Moreover, by comparing Ex. 1 with Ex. 9, it can be seen that as the component (e-3), alumina is preferred as compared to zinc oxide; and by comparing Ex. 1 with Ex. 7, it can be seen that the thermally conductive silicone adhesive composition according to the present invention wherein the content of component (e-1) is higher than that of component (e-2) exhibits better desired performances than that wherein the content of component (e-1) is lower than that of component (e-2).

In contrast, the thermally conductive silicone adhesive compositions which are not according to the present invention (Ex. 2 to Ex. 6 and Ex. 8) did not exhibit a thermal impedance lower than 0.06 K·cm²/W, a viscosity of 100 to 300 Pa·s at 25° C., a breakdown voltage higher than 3 kV/mm, and a good anti-pump-out performance of −40 to 125° C. for 200 cycles at the same time. For example, all of Ex. 2 to 3 (containing zinc oxide or alumina instead of the component (e-2)) and Ex. 4 to 5 (containing SiC having a D₅₀ particle size of 20 or 5 μm instead of the component (e-2)) exhibited thermal impedances higher than 0.06 K·cm²/W, Ex. 4 exhibited a viscosity less than 100 Pa·s at 25° C. and a breakdown voltage lower than 3 kV/mm, and both Ex. 3 and Ex. 4 failed to exhibit a good anti-pump-out performance of −40 to 125° C. for 200 cycles. Ex. 6 (containing alumina having a D₅₀ particle size of 3 μm in addition to the component (E)) exhibited a thermal impedance higher than 0.06 K·cm²/W and failed to exhibit a good anti-pump-out performance of −40 to 125° C. for 200 cycles. Ex. 8 (containing alumina having a D₅₀ particle size of 10 μm instead of the component (e-1)) exhibited a thermal impedance higher than 0.06 K·cm²/W and failed to exhibit a viscosity of 100 to 300 Pa·s at 25° C.

Although some preferred embodiments have been described, many modifications and variations may be made thereto in light of the above teachings. It is therefore to be understood that the invention may be practiced otherwise than as specifically described without departing from the scope of the appended claims.

What is claimed is:

1. A thermally conductive silicone adhesive composition comprising:
(A) an alkenyl group-containing organopolysiloxane;
(B) an alkyl group-terminated organopolysiloxane;
(C) a silane coupling agent;
(D) a catalyst; and
(E) a mixture of (e-1) alumina having a D₅₀ particle size of 4 to 8 μm, (e-2) silicon carbide having a D₅₀ particle size of 1 to 4 μm, and (e-3) alumina and/or zinc oxide having a D₅₀ particle size less than 1 μm.

2. The thermally conductive silicone adhesive composition according to claim 1, wherein the component (e-1) has a D₅₀ particle size of 4.5 to 7 μm.

3. The thermally conductive silicone adhesive composition according to claim 1, wherein the component (e-2) has a D₅₀ particle size of 1.5 to 3.5 μm.

4. The thermally conductive silicone adhesive composition according to claim 1, wherein the component (e-3) has a D₅₀ particle size less than 0.8 μm.

5. The thermally conductive silicone adhesive composition according to claim 1, containing no filler except the component (E).

6. The thermally conductive silicone adhesive composition according to claim 1, wherein the component (e-1) is present in an amount of from 10 to 80% by weight, each based on the total weight of the composition.

7. The thermally conductive silicone adhesive composition according to claim 1, wherein the component (e-2) is present in an amount of from 5 to 70% by weight, each based on the total weight of the composition.

8. The thermally conductive silicone adhesive composition according to claim 1, wherein the component (e-3) is present in an amount of from 1 to 40% by weight, each based on the total weight of the composition.

9. The thermally conductive silicone adhesive composition according to claim 1, wherein the component (A) is a vinyl terminated polydimethylsiloxane having a viscosity lower than 200 mPa·s at 25° C.

10. The thermally conductive silicone adhesive composition according to claim 1, wherein the component (B) is a methyl-terminated polydimethylsiloxane having a viscosity lower than 200 mPa·s at 25° C.

11. The thermally conductive silicone adhesive composition according to claim 1, wherein the component (C) is trimethoxysilane.

12. The thermally conductive silicone adhesive composition according to claim 1, wherein the component (D) is a platinum-based catalyst.

13. A cured product of the thermally conductive silicone adhesive composition according to claim 1.

14. A method of manufacturing an electronic device comprising:
(a) applying the thermally conductive silicone adhesive composition according to claim 1 to a surface of a pair of substrates for an electronic device;
(b) bringing the pair of substrates into contact with each other such that the thermally conductive silicone adhesive composition lies between the pair of substrates;
(c) curing the thermally conductive silicone adhesive composition, before and/or after (b), thereby forming a cured product of the thermally conductive silicone adhesive disposed between the pair of substrates;
(d) assembling the electronic device to include the pair of substrates comprising the cured product therebetween.

15. The method of manufacturing electronic devices according to claim 14, wherein the electronic device comprises one or more of an Insulate-Gate Bipolar Transistor (IGBT) module for power, a telecommunication device and a data communication device.

16. The thermally conductive silicone adhesive composition according to claim 1, wherein the component (e-1) is present in an amount of from 10 to 80% by weight; the component (e-2) is present in an amount of from 5 to 70% by weight; and the component (e-3) is present in an amount of from 1 to 40% by weight, each based on the total weight of the composition.

17. The thermally conductive silicone adhesive composition according to claim 16, wherein the component (e-1) has a D₅₀ particle size of 5 to 6 μm; the component (e-2) has a D₅₀ particle size of 2 to 3 μm; and the component (e-3) has a D₅₀ particle size less than 0.4 μm.

18. The thermally conductive silicone adhesive composition according to claim 17, wherein the component (A) is a vinyl terminated polydimethylsiloxane; the component (B) is a methyl-terminated polydimethylsiloxane; the component (C) is trimethoxysilane; and the component (D) is a platinum-based catalyst.
